(19) United States
(12) Patent Application Publication
(10) Pub. No.: US 2012/0319918 A1
(43) Pub. Date: Dec. 20, 2012

(54) ANTENNA MATCHING APPARATUS AND METHODS

(76) Inventors: Prasadh Ramachandran, Oulu (FI); Zlatoljub Milosavljevic, Espoo (FI); Muhammad Nazrul Islam, Oulu (FI); Petteri Annamaa, Oulunsalo (FI); Ville Majava, Kiviniemi (FI); Arto Hujanen, Espoo (FI); Matti Somersalo, Espoo (FI)

(21) Appl. No.: 13/502,733

(22) PCT Filed: Oct. 15, 2010
(86) PCT No.: PCT/FI2010/050805

§ 371 Date: Aug. 31, 2012

(30) Foreign Application Priority Data
Oct. 27, 2009 (FI) 20096101

(51) Int. Cl. H03H 7/40; H01Q 1/50

(52) U.S. Cl. 343/852; 333/124; 333/129

(57) ABSTRACT

Apparatus and methods for matching the antenna of a radio device. In one embodiment, a capacitive sensor is arranged in the antenna structure and configured to detect the electric changes in the surroundings of the antenna. The mismatch caused by a change is rectified by means of the signal proportional to the sensor capacitance. This capacitance and the frequency range currently in use are input variables of a control unit. The antenna impedance is adjusted by means of a reactive matching circuit, the component values of which can be selected from a relatively wide array of alternatives by way of change-over switches, which are located in the transverse branches of the matching circuit.

The invention relates to the matching of the antenna of a radio device, and it includes both a matching arrangement and a method. The invention is intended especially for small-sized mobile terminals.

Matching the impedance of the antenna of a radio device to the power amplifier of the transmitter feeding the antenna is a normal arrangement in transmission technology. By means of the matching, the radiation power of the antenna can be made as high as possible in proportion to the power of the power amplifier. The poorer the matching of the antenna, the higher the strength of the field reflected from the antenna towards the power amplifier in proportion to the strength of the field propagating towards the antenna. If a certain transmitting power is wanted even though the matching degrades, the gain of the power amplifier has to be raised, which will result in increased current consumption and possibly problems in heating up in the output stage.

The matching of an antenna can degrade for external and internal reasons. If the device approaches some conductive object, the impedance of the antenna changes. Similarly, already the head of a user and the hand, in which the mobile terminal usually is during the connection, can cause a significant change in the impedance. In addition, in case of a multi-band antenna, changing the operating band changes the antenna impedance, which means a change in the matching. For these kind of facts it is favourable to make the antenna matching adaptable in such a way that it varies to be each time conformable to the circumstances. This requires that an adjustable matching circuit is added to the feed circuit of the antenna. Usually the matching circuit is controlled on grounds of the information of the strength of the field reflected from the antenna so that the antenna matching is all the time as good as possible.

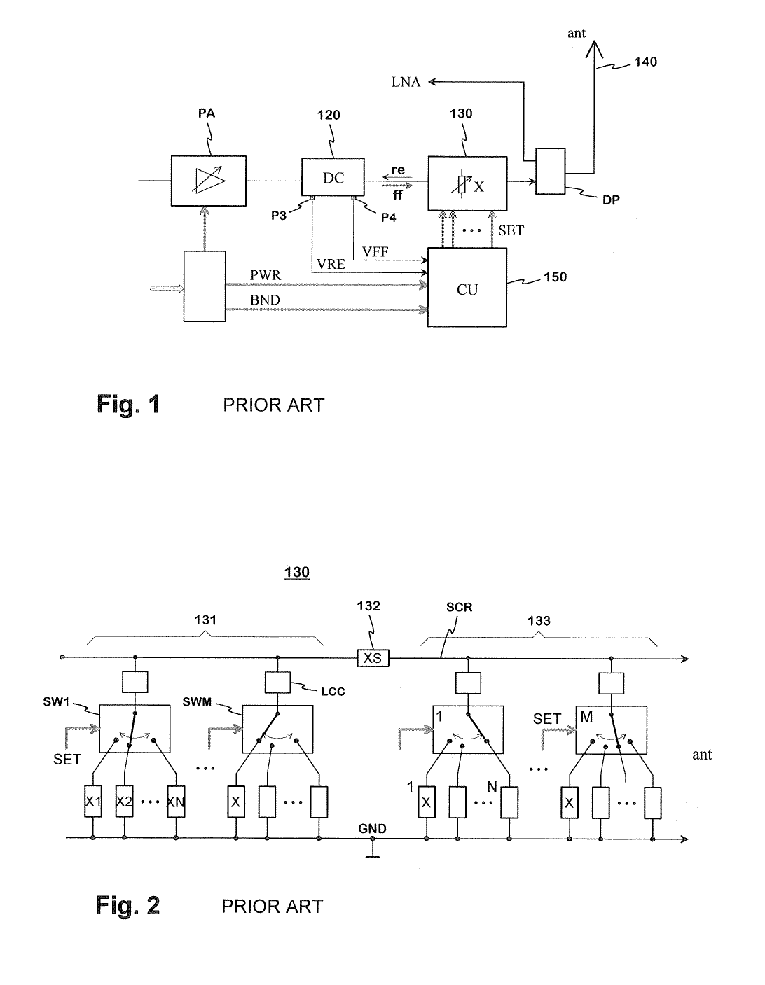

In FIGS. 1 and 2 there is an example of the adaptable matching, known from the publication WO 2008/129125. FIG. 1 shows as a block diagram the transmitting end of a radio device, and FIG. 2 shows the matching circuit belonging to the transmitting end. The transmission path of the transmitter is seen in FIG. 1, which transmission path comprises, connected in series in the direction of the propagation of the signal, the power amplifier PA of the transmitter, a directional coupler 120, a reactive matching circuit 130, a duplexer DP and the antenna 140. By means of the duplexer are separated the transmission directions; the signal received from the antenna is led as filtered to the low-noise amplifier LNA of the receiver. The directional coupler and the matching circuit belong to the antenna's matching arrangement, which further comprises a control unit 150.

The antenna matching can never be perfect, so a certain part re of the field ff propagating to the antenna is reflected back. The directional coupler provides two measuring signals: A radio frequency voltage VRE proportional to the reflected field is received from its port P3 and a radio frequency voltage VFF proportional to the propagating field from its port P4. These measuring signals are converted to direct voltages and further to binary digits in the control unit 150. In addition, the band signal BND indicating the current operating band and the power signal PWR proportional to the set value of the transmitting power are led to the control unit. The output signals SET of the control unit are connected to the matching circuit 130, control signals of which they then are.

The component values of the matching circuit 130 are selected by means of the multiple-way switches, which have a certain total number of state combinations. The control unit 150 executes at regular intervals an adjusting process. The interval of the starting moments in the process is e.g. 10 ms. The standing wave ratio, or SWR, of the antenna is obtained from the measuring signals VRE and VFF provided by the directional coupler. The higher the SWR, the poorer the matching. On grounds of the SWR value, the state of the band signal BND and the state of the power signal PWR the control unit chooses a substantially smaller array from the total array of the state combinations of the switches. In the matching process the switches of the matching circuit are in turn set to each of the state combinations, which belong to said smaller array, and the SWR value of the transmitting signal is read in each setting. Finally in the process the control unit sets the switches to the states, the combination of which corresponds to the lowest of the obtained SWR values.

In FIG. 2 there is the principled structure of the matching circuit 130. The matching circuit is a π-shaped network, which then comprises in order a first transverse portion 131, a longitudinal portion 132 and a second transverse portion 133. The longitudinal portion is simple. It is constituted by a reactive element XS in series with the separate conductor SCR of the antenna transmission path, which element has a certain constant capacitance or inductance. Each transverse portion comprises at least one multiple-way switch SW1, SWM with multiple states, the common terminal of which is coupled to the separate conductor SCR and each change-over terminal is coupled to the ground conductor of the transmission path, or the signal ground GND, through a reactive element X1, X2, XN. Each switch can be separately set to any state by the control SET of the matching circuit coming from the control unit 150. In FIG. 2 the number of the switches in each transverse portion is marked by the symbol M. If the number of the reactive elements to be selected by each switch is N, the total number of the state combinations is N^{2M}. If e.g. M is two and N is four, the total number of the state combinations is 256. The number of the switches in the first and second transverse portion can be unequal, and the number of the reactive elements to be selected by one switch is independent of the corresponding number of the other switches.

Between each switch and the separate conductor SCR of the transmission path there is a circuit LCC, the object of which is usually to function as an ESD (ElectroStatic Discharge) protector for the switch. In addition, the serial capacitor belonging to the LC circuit functions, when needed, as a blocking capacitor preventing the forming of a direct current circuit from the switch control through the conductor SCR.

The branches in the transverse portions of the matching circuit, each branch including a change-over switch and alternative reactive elements, can naturally be also inverted so that the common terminals of the switches are connected to the ground conductor and one end of each reactive element to the separate conductor of the transmission path. One reactive element is then connected between the conductors of the transmission path at a time.

A drawback of the above-described solution is that the linear operating range of the directional coupler, being for the measurement of the antenna's mismatch, is relatively limited. In addition, the directional coupler is located on the transmission path of the transmitting signal, which means a certain extra loss in the transmitter. A drawback is also that the adjusting algorithm is relatively complex regardless of the fact that the number of the switches' state combinations, which are taken into account, is reduced in the early stage of the adjustment. A further drawback of the solution is that it is not suitable for the adjustment of the receiver matching.

An object of the invention is to implement the adaptable antenna matching in a way which reduces the above-mentioned drawbacks. The arrangement according to the invention is characterized in that which is specified in the independent claim 1. The method according to the invention is characterized in that which is specified in the independent claim 12. Some advantageous embodiments of the invention are presented in the dependent claims.

The basic idea of the invention is the following: A capacitive sensor is arranged in the antenna structure for detecting the electric changes in the surroundings of the antenna. The mismatch caused by a change is rectified by means of the signal proportional to the capacitance of the sensor. This capacitance and the frequency range currently in use are input variables of the control unit. The antenna impedance is adjusted by means of a π-shaped reactive matching circuit, the component values of which can be selected from a relatively wide array of the alternatives by means of change-over switches, which are only located in the transverse portions of the matching circuit. The control unit executes an adjusting process at regular intervals, on grounds of the result of which process it selects the combination of the component values of the matching circuit and sets the switches.

An advantage of the invention is that the antenna matching keeps relatively good, although the impedance from the duplexer towards the antenna would strive to change for external reasons or because of a band exchange. Maintaining the impedance results in that the mean efficiency of the transmitter improves, the level of the harmonic frequency components springing up in the power amplifier lowers and the function of the filters in the transmitter becomes more linear. Another advantage of the invention is that no directional coupler and serial adjusting components are needed in the transmission path of the transmitter, in which case the losses of the transmission path decrease and the efficiency of the transmitter improves also for this reason. A further advantage of the invention is that it can be used for the antenna matching also during the receiving. A further advantage of the invention is that the algorithm to be used in the adjusting process is relatively simple and fast compared to the known algorithms.

Below, the invention is described in detail. Reference will be made to the accompanying drawings where:

FIG. 1 presents as a block diagram an example of the adaptable matching according to the prior art,

FIG. 2 presents an example of the structure of the matching circuit in FIG. 1,

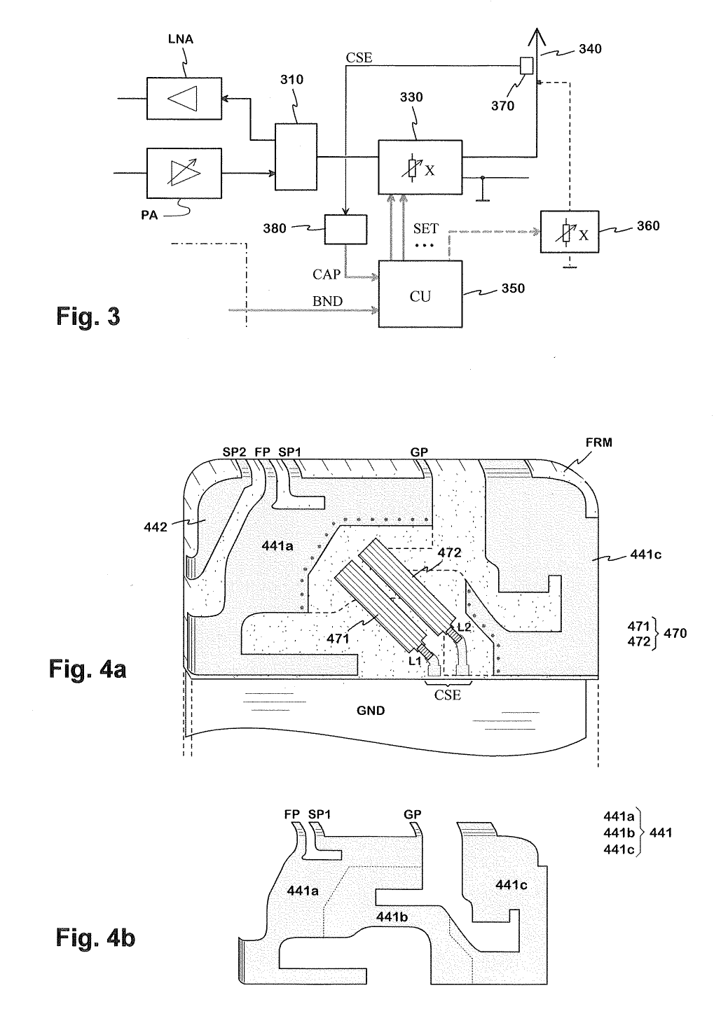

FIG. 3 presents as a block diagram an example of the arrangement according to the invention,

FIGS. 4a,b present an example of the sensor belonging to the arrangement according to the invention in the antenna structure,

FIG. 5 presents a second example of the arrangement according to the invention.

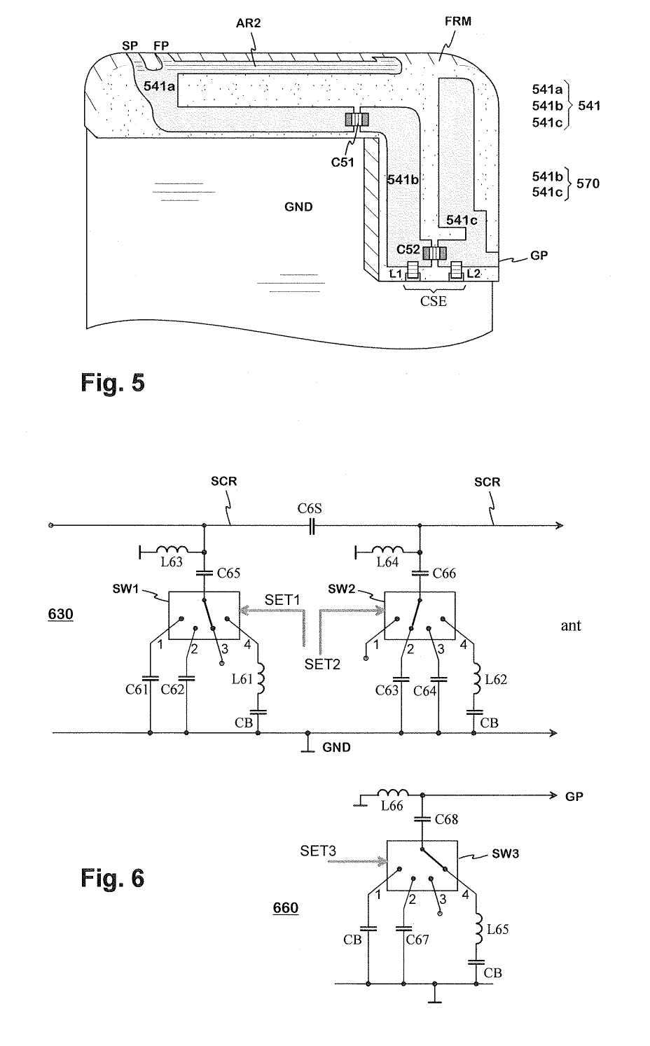

FIG. 6 presents an example of the matching circuit belonging to the arrangement according to the invention,

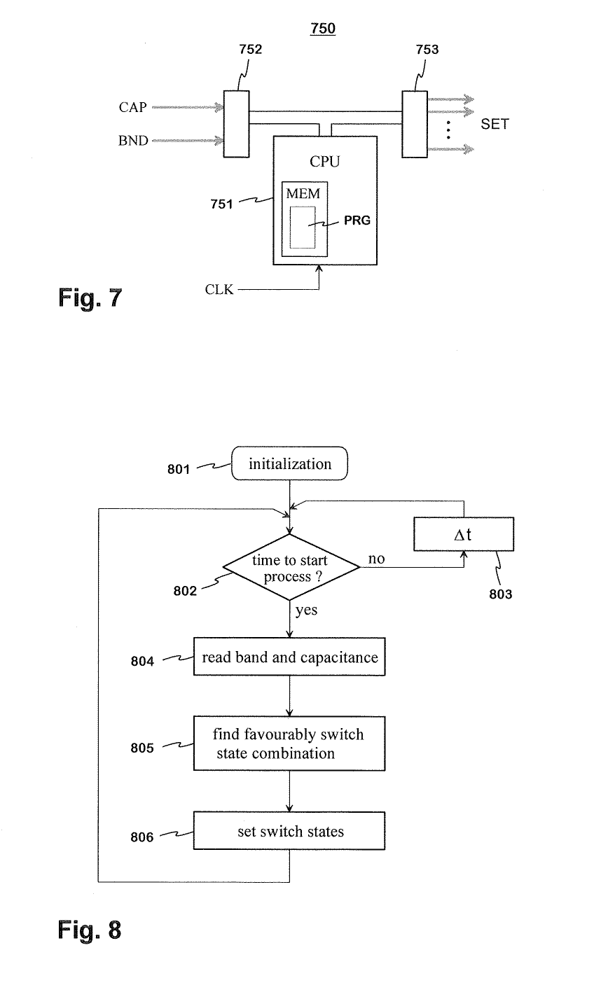

FIG. 7 presents as a block diagram the principled structure of the control unit belonging to the arrangement according to the invention,

FIG. 8 presents as a flow chart an example of the method according to the invention,

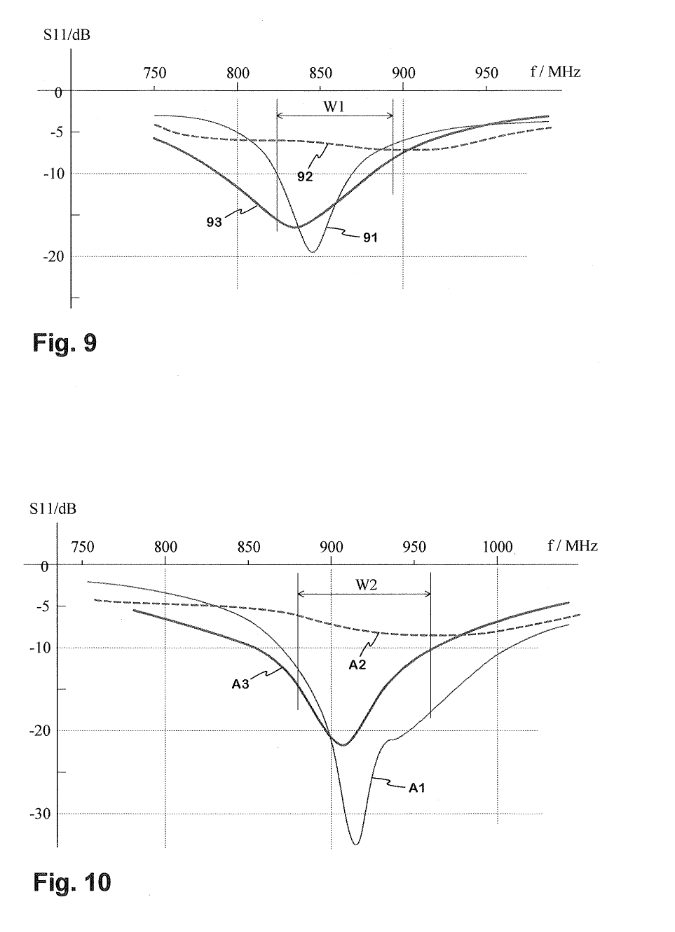

FIG. 9 presents by means of the reflection coefficient an example of the improvement of the matching of an antenna by means of the arrangement according to the invention,

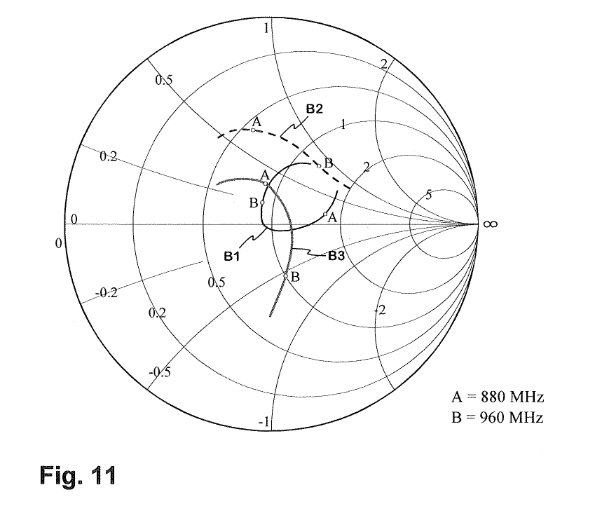

FIG. 10 presents by means of the reflection coefficient another example of the improvement of the matching of an antenna by means of the arrangement according to the invention,

FIG. 11 presents by means of the Smith diagram an example of the improvement of the matching of an antenna by means of the arrangement according to the invention,

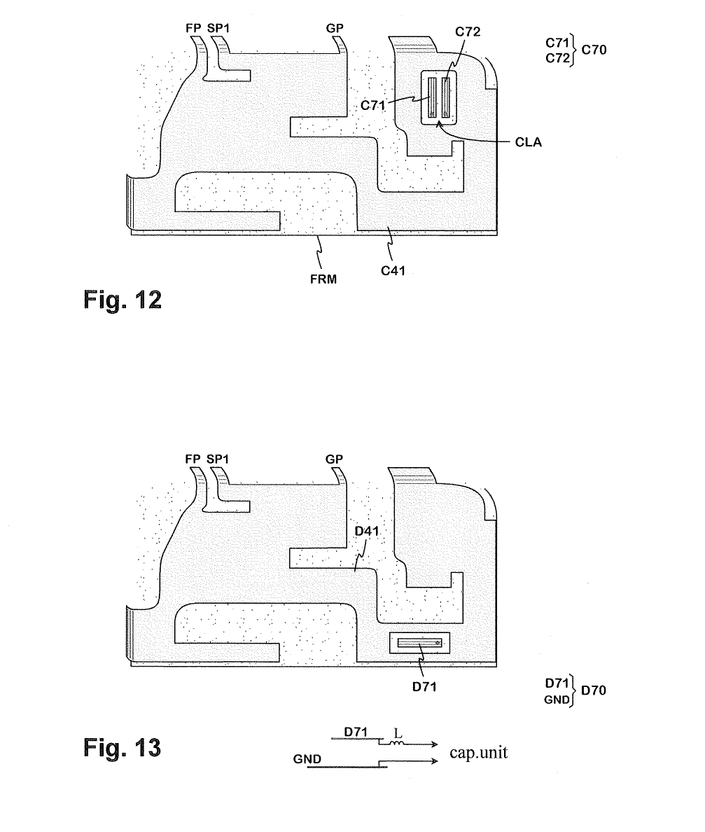

FIG. 12 presents a third example of the sensor belonging to the arrangement according to the invention, and

FIG. 13 presents a fourth example of the sensor belonging to the arrangement according to the invention.

FIGS. 1 and 2 were already explained in conjunction with the description of the prior art.

FIG. 3 shows as a block diagram an example of the arrangement according to the invention in a radio device. The transmission path of the antenna end of the radio device is seen in the figure, which path comprises a duplexer 310, a reactive first matching circuit 330 and the antenna 340 itself. The transmission directions are separated by the duplexer; the signal to be fed to the antenna comes to it from the power amplifier PA of the transmitter, and the signal received from the antenna is led as filtered from the duplexer to the low-noise amplifier LNA. When using e.g. the TDD technique (Time Division Duplex), the duplexer is a multiple-way switch by structure. In addition, a second matching circuit 360 is seen in FIG. 3, which is connected between a certain point in the antenna radiator and the ground plane of the antenna. The dashed line in FIG. 3 means that the second matching circuit is not necessary from the viewpoint of the invention. The matching circuits 330, 360 are controlled by the control unit 350.

Close to a radiator of the antenna there is a capacitive sensor 370. This is connected to a capacitance unit 380, which converts the capacitance CSE of the sensor to a binary signal CAP, the level of which is proportional to said capacitance. The capacitance is measured using a low frequency (e.g. 35 kHz) current fed to it. This capacitance signal CAP is led to the input of the control unit 350. The sensor, the capacitance unit, the control unit and the first matching circuit constitute the matching arrangement according to the invention.

Information about the changes in the surroundings of the antenna is acquired by the sensor. If a conductive and/or dielectric object, such as a finger of the user, comes near to the antenna, the antenna impedance changes. Also the capacitance CSE of the sensor changes for the same reason, and therefore it can be used in the rectification of the antenna matching. In FIG. 3, the second input signal of the control unit is the band signal BND received from the control part of the whole radio device, which signal indicates the current frequency range being in use. Already a relatively small change in the carrier frequency, for example from the band of the GSM850 system (Global System for Mobile telecommunications) to the band of the GSM900 system, causes a significant impedance change in the antenna, for which reason the matching has to be rectified.

The outputs SET of the control unit are connected to the first 330 and second 360 matching circuit for selecting reactances in them. The control unit executes at regular intervals the adjusting process pursuant to a certain algorithm, in which process the control of the first matching circuit is determined on grounds of the level, or value, of the capacitance signal CAP and band signal BND. The second matching circuit 360 is primarily controlled on grounds of the band signal BND. When the GSM850 system is exchanged to GSM900 system or vice versa, the antenna's operating band is shifted correspondingly by means of the second matching circuit, the antenna matching being thereby improved.

FIGS. 4a and 4b show an example of the sensor belonging to the arrangement according to the invention in the antenna structure. FIG. 4a shows the whole antenna with the sensor, and FIG. 4b shows the bare main radiator, or radiating main element, of the antenna. The end of a radio device, at which its antenna is located, is seen in the drawing. The radiators of the antenna are of conductive coating of a dielectric frame FRM, which forms here the cover of the end part of the device. The supporting frame of the radiators can also be e.g. a separate flexible dual-layer circuit board. In this example the antenna includes two radiating elements, the main element 441, in which the antenna feed point FP is, and a parasitic element 442. Also the ground plane GND belongs to the antenna, which plane is located below the radiators on the circuit board of the radio device. The main element is connected also to the ground plane from the first short-circuit point SP1, and the parasitic element is connected to the ground plane from the second short-circuit point SP2 at one end. The main element branches, seen from its short-circuit point SP1, to two arms of different lengths to implement two operating bands for the antenna. The antenna part, which corresponds to the longer arm of the main element, resonates in the lower operating band, and the antenna part, which corresponds to the shorter arm of the main element, resonates in the higher operating band. Also the antenna part, which corresponds to the parasitic element, resonates in the higher operating band widening this band.

The sensor 470 consists of the first 471 and the second 472 electrode, which are distinct conductor strips on the outer surface of the antenna frame FRM. The conductor strips are so close to each other that a clearly higher capacitance than different stray capacitances exists between them. A coil L1; L2 is in series with each electrode, between it and a conductor of the line, which connects the sensor to the capacitance unit 380. The impedance of these coils is very high at the radio frequencies. Therefore no radio-frequency currents can be generated in the line between the sensor and capacitance unit 380, and the circuit of the sensor then does not cause losses and change the antenna impedance.

The sensor is located close to the main element of the antenna in the space of its near field. In addition, the sensor is placed in the area, where the electric field of the main element has a minimum at its lower resonance frequency, in which case the sensor degrades the antenna function as little as possible. The area in question is located in the middle part of the longer arm of the main element. In order to avoid a short between the sensor strips and the main element, the middle part 441b of the longer arm of the main element is located on the inner surface of the frame FRM. This middle part joins the starting part 441a and the tail part 441c of the longer arm of the main element through the conductive vias locating close enough to each other. Alternatively, the main element would be wholly located on the outer surface of the frame, and the sensor would be insulated from it by a dielectric layer.

In the example of FIG. 4a the main radiator 441 of the antenna has also a grounding point GP, from which it is intended to connect to the ground plane through the second matching circuit 360 visible in FIG. 3.

FIG. 5 shows a second example of the arrangement according to the invention. The main radiator, or the main element 541 of the antenna is of conductive coating of the dielectric frame FRM. Other elements are not visible, but may be in the structure. The main element is connected to antenna port of the radio device from the feed point FP and to the ground plane GND from the short-circuit point SP. Also in this example the main element branches, seen from its short-circuit point SP, to the longer arm for implementing the lower operating band and to the shorter arm AR2 for implementing the higher operating band.

The sensor 570 consists of two electrodes, which are in this embodiment parts of the longer arm of the main element 541. The first electrode is the middle part 541b of the longer arm, and the second electrode is the tail part 541c of the longer arm. For this purpose the middle part 541b is galvanically separated from the rest 541a of the main element and from the tail part 541c. However, the middle part is coupled to the rest 541a of the main element by a capacitor C51 and to the tail part by a capacitor C52, the capacitances being e.g. 70 pF. The impedance of these capacitors is then very low (about 2Ω) at the radio frequencies, for which reason the longer arm of the main element is united in the operating band. At the use frequency (35 kHz) of the sensor the impedance of these capacitors is about 20 kΩ, which represents a good separation between the electrodes. The middle part 541b and tail part 541c are located mostly parallelly so that there is a suitable capacitance CSE between them. A coil L1; L2 is in series with each electrode, the impedance of which coils is very high at the radio frequencies. Therefore no radio-frequency currents can be generated in the line between the sensor and capacitance unit, and the circuit of the sensor then does not cause losses and change the antenna impedance.

In this example the sensor is located in the area where the electric field of the main element is relatively strong at its lower resonance frequency. The area of the weak electric field is not so useful here because of the typical location of the user finger during communication.

FIG. 6 shows a simple example of the matching circuits belonging to the arrangement according to the invention. Both the first matching circuit 630 on the transmission path of the antenna and the second matching circuit 660 to be connected between the grounding point GP and ground plane occur in the example.

The first matching circuit is a π-shaped network, which then comprises in order a first trans-verse portion, a longitudinal portion and a second transverse portion. Each transverse portion comprises one change-over switch, and the number of the reactive elements to be chosen by each switch is four. In this case the total number of the state combinations of the first matching circuit is 16. The first reactive element of the first switch SW1 is the capacitor C61, in other words the first change-over terminal of the switch SW1 is connected to the ground conductor of the transmission path, or the signal ground GND, through this capacitor C61. Correspondingly, the second reactive element of the first switch is the capacitor C62, the third ‘reactive element’ is an open circuit representing then a very high reactance, and the fourth reactive element is the coil L61. In series with the coil L61 there is a blocking capacitor CB for breaking the direct current path from the switch control. The capacitance of the blocking capacitors is so high, for example 100 pF, that they constitute almost a short-circuit at the operating frequencies of the antenna. The first reactive element of the second switch SW2 is an open circuit representing then a very high reactance. The second reactive element of the second switch is the capacitor C63, the third reactive element is the capacitor C64 and the fourth reactive element is the coil L62. In series with the coil L62 there is a blocking capacitor CB. The longitudinal portion of the first matching circuit is constituted by the capacitor C6S, in series with the parts of the separate conductor SCR of the transmission path.

Between the common terminal of switch SW1 and the separate conductor SCR there is the capacitor C65, and between the end of this capacitor on the side of the conductor SCR and the ground plane there is the coil L63. Correspondingly, between the common terminal of switch SW2 and the separate conductor SCR there is the capacitor C66, and between the end of this capacitor on the side of the conductor SCR and the ground plane there is the coil L64. The LC circuits C65-L63 and C66-L64 function as ESD protectors for the switches. In addition, the capacitors C65 and C66 function as a blocking capacitor preventing the forming of a direct current circuit from the control of switches SW1 and SW2 to the conductor SCR.

The first switch SW1 is set by the first control signal SET1 and the second switch SW2 is set by the second control signal SET2. These control signals are two-bit binary digits, corresponding to the number of the switching alternatives.

In the second matching circuit 660 there is the third switch SW3 and four alternative reactive elements to be chosen by this switch. The first reactive element is a bare blocking capacitor, which represents at the radio frequencies a short-circuit, or a very low reactance. The second reactive element is the capacitor C67, the third reactive element is an open circuit representing then a very high reactance and the fourth reactive element is the coil L65, in series with which there is a blocking capacitor CB. Between the common terminal of switch SW3 and the grounding point GP of the radiator there is the capacitor C68, and between the end of this capacitor on the side of the grounding point GP and the ground plane there is the coil L66. The circuit C68-L66 functions as an ESD protector for the switch. In addition the capacitor C68 functions as a blocking capacitor preventing the forming of a direct current circuit from the control of switch SW3 to the ground through the radiator.

The third switch SW3 is set by the third control signal SET3, which is in this example a two-bit binary digit.

FIG. 7 shows as a block diagram an example of the principled structure of the control unit belonging to the arrangement according to the invention. The control unit 750 is based on a processor, in which case it comprises a central processing unit 751 provided with a memory MEM. The central processing unit connects through a bus to the interface ports. One part of the ports is used as input interfaces 752 and another part as output interfaces 753. The input signals of the control unit are the capacitance signal CAP and band signal BND. The central processing unit 751 reads them from the input interfaces 752. The control data SET corresponding to the state combination of the switches in the matching circuit(s), selected as a result of the adjusting process, is transferred to the output interfaces 753 by the central processing unit, which interfaces send the data further to the matching circuit(s).

The memory MEM of the control unit contains i.a. the matching program PRG, which implements the adjusting process of the matching in accordance with a certain algorithm. The process is started again at regular intervals, and the interval of the startings is counted either by software or by a timer circuit being included in the central processing unit 751. Of course, the central processing unit needs in any case a clock signal CLK.

By structure, the control unit can also be a bare hardware logic without any central processing unit proper with software.

FIG. 8 shows as a flow chart an example of the method according to the invention. In the starting step 801 the control unit and matching circuits are initialized to a certain basic state. In steps 802 and 803 it is waited until the deadline for starting the adjusting process of the antenna matching expires. In step 804 the current frequency range and the capacitance of the sensor are found out by reading the values of the band signal BND and capacitance signal CAP. In step 805 is selected, on grounds of the values of the band signal and capacitance signal, the supposedly optimal state combination from the total array of the state combinations of the switches in the matching circuit(s). Finally, in step 806, the switches in the matching circuit are set to the above-selected states. The optimal state combination means such a combination, by which the antenna matching is as good as possible under the current circumstances. In matching the impedance, which affects from the duplexer seen in FIG. 3 towards the antenna, is intended to have the same value as the nominal impedance. After step 806 it is returned to step 802 for waiting the starting moment of the next execution round of the process. The interval of the starting moments is e.g. 10 ms. The duration of the process is remarkably shorter, e.g. 1 ms.

The search of the state combinations of the switches in the adjusting process takes place in accordance with a certain algorithm. The algorithm can be based on a table, in which the optimal state combinations corresponding to different values of the input signals have been stored. The input signals are then used to address the memory in which the table is. A research and measurement activity precedes the forming of the table by which activity the sufficient extent of the π-shaped matching circuit, in other words the number of the transverse portions and the number of the alternative reactances in each portion and favourable component values for the reactances, is found out.

In FIG. 9 there is an example of the matching of an antenna provided with an arrangement according to the invention, shown by means of the reflection coefficient. The antenna is like the one in FIG. 4a, and the arrangement comprises the first and the second matching circuit like the ones in FIG. 6. The component values of these circuits are as follows: C6S=5.1 pF, C61=1.6 pF, C62=4.3 pF, L61=2.7 nH, C63=1.6 pF, C64=4.3 pF, L62=2.7 nH, C67=1.0 pF and L65=2.7 nH. Each CB=100 pF. (Here the symbol Cij means both a certain component and its capacitance, correspondingly Lij.) The example relates to the matching in the frequency range 824-894 MHz of the GSM850 system, which range has been marked W1 in FIG. 9.

Curve 91 shows the fluctuation of the reflection coefficient S11 as a function of frequency when the antenna is almost in a free space. Switch SW1 is in state ‘1’ and switch SW2 in state ‘2’. It is seen from the curve that the reflection coefficient varies between the values 6.4 dB and −19.4 dB in the frequency range W1, being about −12 dB on average. Curve 92 shows the fluctuation of the reflection coefficient when a finger of the user is at the antenna on the radiator, and the switches are in the same states as before. It is seen from the curve that the reflection coefficient varies between the values −6.0 dB and −7.0 dB in the frequency range W1, being −6.5 dB on average. Thus the matching has clearly degraded. Curve 93 shows the fluctuation of the reflection coefficient when the finger of the user is still in the same place on the radiator, and the switches of the first matching circuit are set in a new way. Now switch SW1 is in state ‘2’ and switch SW2 in state ‘4’. It is seen from the curve that the reflection coefficient varies between the values −8.3 dB and −16.5 dB in the frequency range W1, being about 13 dB on average. Thus the matching has clearly improved.

In FIG. 10 there is another example of the matching of an antenna provided with an arrangement according to the invention, shown by means of the reflection coefficient. The example relates to the same antenna and matching arrangement as the example of FIG. 9, the frequency range being now 880-960 MHz used by the extended GSM900 system. This range has been marked W2 in FIG. 10. Curve A1 shows the fluctuation of the reflection coefficient S11 as a function of frequency when the antenna is almost in a free space, curve A2 shows the fluctuation when a finger of the user is at the antenna on the radiator, and curve A3 when the finger of the user is still in the same place on the radiator and the switches of the matching circuits are set in a new way. In the first case switch SW1 is in state and switch SW2 in state ‘2’. The reflection coefficient in the frequency range W2 is about −22 dB on average. In the second, or mismatch, case the switches are unchanged and the reflection coefficient is about −8 dB on average. In the third case switch SW1 is set to state ‘2’ and switch SW2 remains in state ‘2’. It is seen from curve A3 that the reflection coefficient is about −17 dB on average. Thus the control of the matching circuits has clearly improved the matching.

As mentioned, the second matching circuit 660 is used for improving the matching by tuning the resonance frequency of the antenna on grounds of the value of the band signal BND, when this value changes. When GSM850 is in use (FIG. 9), switch SW3 is in state ‘1’, which tunes the lower operating band to said range W1. When GSM900 is in use (FIG. 10), switch SW3 is in state ‘3’, which tunes the lower operating band to said range W2. These states relate to the circumstances where the device is in free space or the mismatch is minor. Depending on the measured capacitance, also another state can be chosen for switch SW3. For example, state ‘3’ may be most favourable, although GSM850 is in use.

FIG. 11 shows an example of the matching of an antenna provided with an arrangement according to the invention, shown by means of the Smith diagram. In the example the antenna, the matching circuits and the frequency range are the same as in the example of FIG. 10. The impedance curves in the diagram correspond then to the curves of the reflection coefficient in FIG. 10: Curve B1 shows the fluctuation of the impedance as a function of frequency in the range W2, when the antenna is almost in a free space, curve B2 shows the fluctuation of the impedance when a finger of the user is at the antenna on the radiator, and curve B3 shows the fluctuation of the impedance when a finger of the user still is in the same place on the radiator, and the switches are set in a new way.

The nominal impedance of the transmission path is 50Ω. In the case of curve B1 the overall impedance is very close to it in the middle range, the reactive part being small. At the borders of the range the impedance is sligthly inductive. In the case of curve B2 the mismatch is clearly visible, the impedance changing about from the value 28Ω+j33Ω to value 65Ω+j41Ω when moving from the lower border of the range to the higher border. The impedance is then clearly inductive. In the matching case, shown by curve B3, the impedance changes about from the value 43Ω+j17Ω to value 50Ω−j26Ω when moving from the lower border of the range to the higher border and is in the middle range purely resistive, about 60Ω.

The quality of the antenna can be considered also by means of its efficiency. When the frequency range 824-894 MHz of the GSM850 system is chosen, the efficiency of the above-mentioned antenna is on average −3.7 dB in free space. The value 0 dB corresponds to the ideal, or lossless, case. In the mismatch case corresponding to curve 92 in FIG. 9 the efficiency is only −7.2 dB on average. In the matching case corresponding to curve 93 in FIG. 9 the efficiency is −4.7 dB on average, which means an improvement of about 2.5 dB in respect of the preceding situation. When the frequency range 880-960 MHz of the GSM900 system is chosen, the efficiency of the same antenna is on average −2.1 dB in free space. In the mismatch case corresponding to curve A2 in FIG. 10 the efficiency is only −7.4 dB on average. In the matching case corresponding to curve A3 in FIG. 10 the efficiency is −5.1 dB on average, which means an improvement of about 2.3 dB in respect of the preceding situation.

As it appears from the description of FIG. 4a, the antenna in the example has also a higher operating band falling into the range of 1.7-2.0 GHz. In the prototype of the arrangement according to the invention, from which the above-described results have been obtained, the compensation of the fluctuation of the antenna impedance is not implemented in the higher operating band. However, it is naturally possible by means of the same principle as in the different frequency ranges of the lower operating band of the antenna by placing another capacitive sensor at the antenna part, which corresponds to the higher operating band. In that case, the matching circuit has to be extended in respect of the example in FIG. 6. In addition, at higher frequencies more attention has to be paid to the losses of the switching components. The switches can be for example of PHEMT (Pseudomorphic High Electron Mobility Transistor) or MEMS (Micro Electro Mechanical System) type.

FIG. 12 shows a third example of the sensor belonging to the arrangement according to the invention. The main element C41 of the antenna is on the surface of a frame FRM, and the sensor C70 consists of the first C71 and the second C72 electrode which are conductor strips on the surface of the frame, like in FIG. 4a. In this case these electrodes are located in an area CIA cleared from the radiating conductor of the main element. The location of the sensor is here relatively close to the outer end of the longer arm of the main element C41. The sensor electrodes are coupled to the control unit through small coils.

FIG. 13 shows a fourth example of the sensor belonging to the arrangement according to the invention. The main element D41 of the antenna is on the surface of a frame FRM, like in FIG. 4a. The capacitive sensor D70 consists of the first electrode D71 and the part of the ground plane GND at the first electrode. This electrode is located on the surface of the frame in an area cleared from the radiating conductor, along the longer arm of the main element D41. The sensor is connected to the capacitance unit by a line with a ground conductor and a conductor coupled to the first electrode through a small coil.

The arrangement and method according to the invention for matching the antenna of a radio device has been described above. The implementation of the reactive elements of the matching circuit belonging to the arrangement can vary. At least a part of them can be also short planar transmission lines on the surface of a circuit board. The term ‘change-over switch’ covers in this description and claims also the structures, where the reactance is changed by changing the control voltage of a varactor-type capacitive element. The location of the sensor in respect of the radiator can naturally vary. The invention does not limit the structure and type of the antenna proper. The inventive idea can be applied in different ways within the scope defined by the independent claims 1 and 12.

1.-14. (canceled)

15. Antenna matching apparatus for use in a radio device having a radio frequency transceiver, the matching apparatus comprising:
a first conductive path;
a second conductive path;
a plurality of secondary electrical paths formed between the first and second conductive paths; each of the secondary electrical paths comprising a multiple position switch having respective reactive components associated with each of said multiple positions; and
control logic operative to actuate the switches so as to, during both transmission and receipt of radio frequency signals, effect matching of the antenna using at least a portion of the reactive components.

16. The matching apparatus of claim 15, wherein the first conductive path comprises a capacitance disposed therein, said capacitance disposed electrically between a first and second one of said plurality of secondary electrical paths.

17. The matching apparatus of claim 15, wherein the respective reactive components are selected from the group consisting of: (i) inductors; (ii) capacitors; and (iii) a combination of at least one inductor and at least one capacitor in series.

18. The matching apparatus of claim 15, wherein the respective reactive components are selected so as to provide a range of possible reactive values so as to enable said antenna matching under a range of external conditions.

19. The matching apparatus of claim 15, wherein the control logic comprises at least one computer program operative to run on a processor of the radio device.

20. The matching apparatus of claim 15, wherein the control logic utilizes a inputs comprising at least: (i) a level of a first signal relating to a capacitance of a sensor disposed at least proximate the antenna; and (ii) the value of a second signal indicative of an operational frequency band.

21. The matching apparatus of claim 15, wherein the first and second conductive paths comprise portions of a transmission path between the antenna and the transceiver of the radio device.

22. The matching apparatus of claim 15, wherein the matching apparatus is configured to operate with no directional coupling apparatus between the antenna and the radio frequency transceiver.

23. The matching apparatus of claim 22, wherein the operation with no directional coupling apparatus between the antenna and radio frequency transceiver provides an enhanced linear operating range of the matching apparatus and antenna relative to use of a directional coupling apparatus between the antenna and radio frequency transceiver.

24. An antenna for use in a wireless device, the antenna comprising:
at least one main radiating element capable of operating in at least one frequency band;
a sensor disposed proximate the at least one main radiating element and configured to detect electric field changes in the surroundings of the antenna; and
control circuitry operative to utilize at least said detected electric field changes to alter an impedance of the antenna so as to mitigate effects of an impedance mismatch.

25. The antenna of claim 24, wherein the at least one frequency band comprises at least two frequency bands, and said control circuitry is further operative to utilize at least the detected electric field strength and a signal indicative of one of said at least two frequency bands to alter said impedance to mitigate said effects.

26. The antenna of claim 25, wherein the control circuitry comprises at least one matching circuit having a plurality of switches and a plurality of reactive components, the at least one matching circuit operative to switch ones of said plurality of reactive components in or out of a transmission path between said antenna a transceiver of a radio frequency host device in which said antenna is operatively disposed.

27. A method for matching an antenna for use in a radio device, the method comprising:
determining a value of a first signal indicating a frequency range to be used in the radio device; and
determining an adjustment of a reactive first matching circuit disposed in an antenna transmission path of the radio device, the first matching circuit configured to effect the adjustment through selection of a state combination of two or more switches in the first matching circuit based at least in part on: (i) the first signal, and (ii) a second signal relating to sensed capacitance, so as to at least optimize an impedance of the antenna.

28. The method of claim 27, wherein the second signal is proportional to a capacitance sensed by a sensor disposed at least proximate the antenna.

29. The method of claim 27, further comprising iteratively (i) performing said acts of determining, and (ii) applying the adjustment determined in a respective iteration.

30. The method of claim 29, wherein said iterative (i) performing and (ii) applying are performed at a prescribed periodicity.

31. The method of claim 27, wherein said acts of determining and applying are performed substantially in response to an indication of an existing impedance mismatch in said antenna.

32. The method of claim 27, wherein the state combination is selected by at least addressing a memory in which a plurality of different state combinations have been stored, the addressing based at least in part on values of the first and second signals.

33. Apparatus for matching an antenna of a radio device comprising a power amplifier (PA) associated with a transmitter, a low-noise amplifier (LNA) associated with a receiver, and a transmission path from the PA and LNA to an antenna, the apparatus comprising a π-shaped adjustable reactive first matching circuit and a control unit, a longitudinal portion of the first matching circuit comprising at least one of a constant capacitance and/or inductance, and at least one transverse portion comprising at least two branches each with a respective alternative reactive element and a switch, the at least two branches configured so as to couple one reactive element at a time between a first conductor and a ground conductor of the transmission path, an input signal of the control unit indicating a frequency range currently in use, the control unit operative to set the switches and comprising apparatus configured to execute an adjustment of antenna matching;
wherein the apparatus further comprises:
a sensor disposed at least proximate a near field of a radiating main element of the antenna, the sensor comprising a first electrode and a second electrode operative to implement a first capacitance;
a capacitance unit having an input to which said first and second electrodes are operatively coupled so as permit generation of a capacitance signal, the level of the capacitance signal being proportional to said first capacitance; and
apparatus at least associated with the control unit and configured to select a state combination of said switches of the at least two branches of the first matching circuit, based at least in part on the values of the capacitance signal and the input signal, during said adjustment.

34. An apparatus according to claim 33, characterized in that said first and second electrodes of the sensor comprise distinct conductors disposed proximate to said main element of the antenna.

35. An apparatus according to claim 33, characterized in that said first and second electrode of the sensor are each part of said main element, separated galvanically from each other and a remaining portion of the main element.

36. An apparatus according to claim 34, characterized in that the sensor is located upon a part of the main element which corresponds to a lower operating band of a multi-band antenna.

37. An apparatus according to claim 34, characterized in that the sensor is located in an area substantially devoid of any radiating conductor of the main element, said element corresponding to a lower operating band of a multi-band antenna.

38. An apparatus according to claim 33, characterized in that said first electrode of the sensor is located in an area devoid of any radiating conductor of the main element, and said second electrode is a part of a ground plane at the first electrode.

39. An apparatus according to claim 33, characterized by at least one coil disposed electrically between each electrode of the sensor and a conductor of a line which connects the sensor to the capacitance unit, the at least one coil having a high impedance at radio frequencies.

40. An apparatus according to claim 33, wherein the control unit comprises a processor with a memory, a plurality of input interfaces and output interfaces, said apparatus configured to select a state combination of the switches in the first matching circuit comprising a program stored in said memory.

41. An apparatus according to claim 33, wherein each of said at least two transverse portions of the first matching circuit comprises one change-over switch, each change-over switch comprising four change-over terminals.

42. An apparatus according to claim 33, further comprising a second matching circuit controlled by said control unit, the second matching circuit being operatively connected between a grounding point in said radiating main element and said ground, the second matching circuit comprising a change-over switch and two or more alternative reactive elements.

43. An apparatus according to claim 33, wherein at least one of said switches comprises a Pseudomorphic High Electron Mobility Transistor (PHEMT)-based or Micro Electro Mechanical System (MEMS)-based device.

44. A method for matching an antenna of a radio device, the method comprising:
reading a value of a band signal indicating a frequency range currently in use in the radio device;
adjusting a reactive first matching circuit disposed in an antenna transmission path of the radio device by setting a state combination of two or more switches in the first matching circuit based at least in part on a value of the band signal, so as to at least optimize an impedance of the antenna; and
repeating said act of adjusting at least once;
characterized in that the state combination of the two or more switches in the first matching circuit is selected based at least in part on: (i) a level of a capacitance signal, the level being proportional to a capacitance of a sensor disposed at least proximate the antenna; and (ii) the value of the band signal.

45. The method according to claim 44, wherein the state combination of the switches in the first matching circuit is selected by at least addressing a memory in which a plurality of different state combinations have been stored, the addressing based at least in part on binary values of the band signal and capacitance signal.

46. The method according to claim 44, wherein the device further comprises a second matching circuit operatively coupled between a main radiating element of the antenna and a ground plane, and the method further comprises adjustment thereof based at least on (i) the value of the band signal, and (ii) the level of the capacitance signal, said adjustment comprising setting a switch in the second matching circuit.
